(19) United States
(12) Patent Application Publication
(10) Pub. No.: US 2010/0101841 A1
(43) Pub. Date: Apr. 29, 2010

(54) PRINTED CIRCUIT BOARD

(75) Inventor: FA-PING FAN, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY(ShenZheng) CO., LTD., ShenZhen City (CN); HON HAI PRECISION INDUSTRY CO.,LTD., Tu-Cheng (TW)

(21) Appl. No.: 12/537,264

(22) Filed: Aug. 7, 2009

(30) Foreign Application Priority Data
Oct. 29, 2008 (CN) 200810305274.6

(51) Int. Cl. H05K 1/09; H05K 1/00

(52) U.S. Cl. 174/257; 174/258; 174/262

(57) ABSTRACT

A printed circuit board (PCB) is disclosed. The PCB includes a dielectric layer, a power layer, a ground layer, and an electromagnetic interference reducing layer. The dielectric layer includes a central portion and a periphery portion surrounding the central portion. The dielectric layer defines a number of via holes through the periphery portion. The ground layer is adhered to a surface of the dielectric layer, covering both the central portion and the periphery portion. The power layer and the EMI reducing layer are separately adhered to another surface of the dielectric layer facing away from the conductive ground layer. The conductive power layer covers the central portion. The EMI reducing layer substantially covers the periphery portion and is electrically connected to the ground layer via the via holes.

### BACKGROUND

1. Technical Field

The present disclosure relates to printed circuit boards (PCBs) and, particularly, to a PCB capable of reducing external electromagnetic interference (EMI).

2. Description of Related Art

A PCB typically includes a power layer for powering the PCB and a ground layer for grounding the PCB. At the edges of the power layer and the ground layer, electromagnetic field lines fringe outward from the PCB, causing external electromagnetic interference (EMI) problems. To reduce EMI, it is proposed that the ground layer must be sized larger than the power layer. It also has been experientially proved that the larger a size difference between the ground layer and the power layer is, the more excellent EMI reduction can be achieved. The size difference between the ground layer and the power layer can be increased in two ways: increasing the size of the ground layer and decreasing the size of the power layer. However, increasing the size of the ground layer substantially increases the size of the PCB. This is not beneficial for miniaturization of the PCB. Moreover, decreasing the size of the power layer limits the space for circuit design.

Therefore, it is desirable to provide a PCB, which can overcome the above-mentioned problems.

### BRIEF DESCRIPTION OF THE DRAWINGS

FIG. 1 is a planar view of a PCB, according to an exemplary embodiment of the present disclosure.

FIG. 2 is a cross-sectional view taken along a line II-II of FIG. 1.

FIG. 3 is an enlarged view of a portion III of FIG. 2.

FIG. 4 is a cross-sectional view of a PCB, according to another exemplary embodiment.

### DETAILED DESCRIPTION

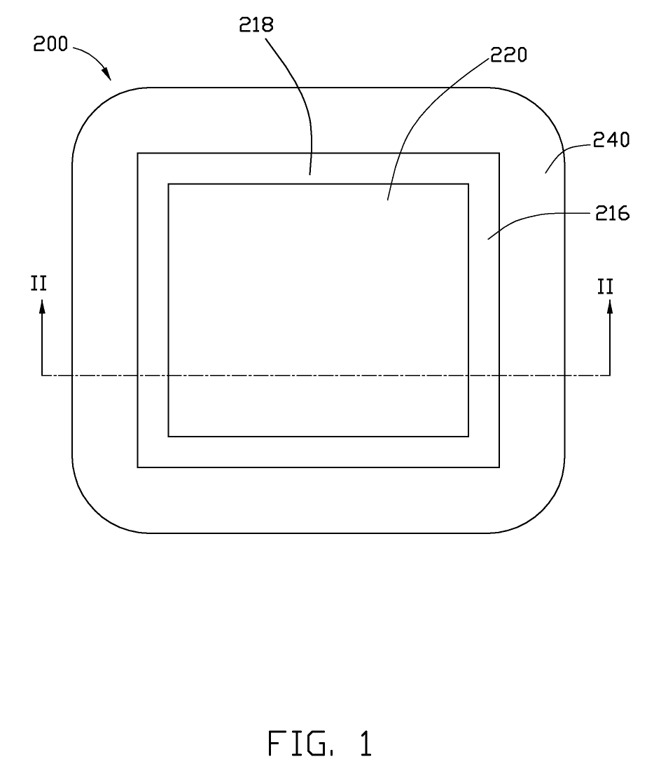

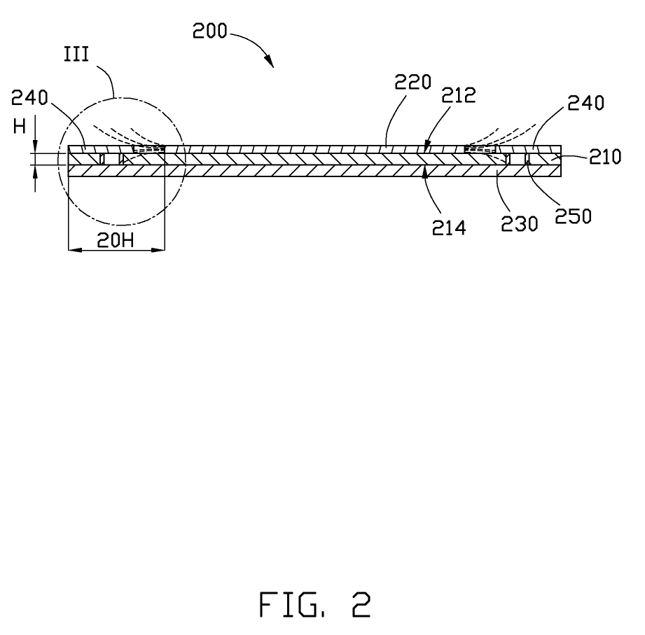

Referring to FIGS. 1-2, a PCB 200, according to an exemplary embodiment of the present disclosure, includes a dielectric layer 210, a power layer 220, a ground layer 230, and an EMI reducing layer 240.

The dielectric layer 210 is made of a dielectric material such as bakelite resin, fiberglass, epoxy resin, or glass-epoxy resin. In this embodiment, the dielectric layer 210 is made of glass-epoxy resin. The dielectric layer 210 includes a first surface 212 and a second surface 214. The dielectric layer 210 defines a number of via holes 250 through a periphery portion 216 of the dielectric layer 210 (i.e., through the first surface 212 and the second surface 214).

The power layer 220 is configured for electrically powering the PCB 200. The ground layer 230 is configured for electrically grounding the PCB 200. The EMI reducing layer 240 is configured for reducing EMI generated by the PCB 200 radiating outwardly (see below). The power layer 220, the ground layer 230, the EMI reducing layer 240 are made of a conductive material such as copper, aluminum, silver, platinum, or gold. In this embodiment, the power layer 220, the ground layer 230, the EMI reducing layer 240 are made of copper.

The ground layer 230 is adhered to the second surface 214, covering the dielectric layer 210. Taking “H” as the distance between the ground layer 230 and the power layer 220 (in this embodiment, H is the height of the dielectric layer 210), the power layer 220 is about 20 H smaller than the ground layer 230, and is adhered to a central portion 218 of the first surface 212, leaving the periphery portion 216 of the dielectric layer 210 exposed. The EMI reducing layer 240 is shaped corresponding to the periphery portion 216 of the dielectric layer 210 and is adhered to the first surface 212 of the dielectric layer 210, separated from the power layer 220 and substantially covering the periphery portion 216 of the first surface 212. The via holes 250 electrically connect the ground layer 230 and the EMI reducing layer 240.

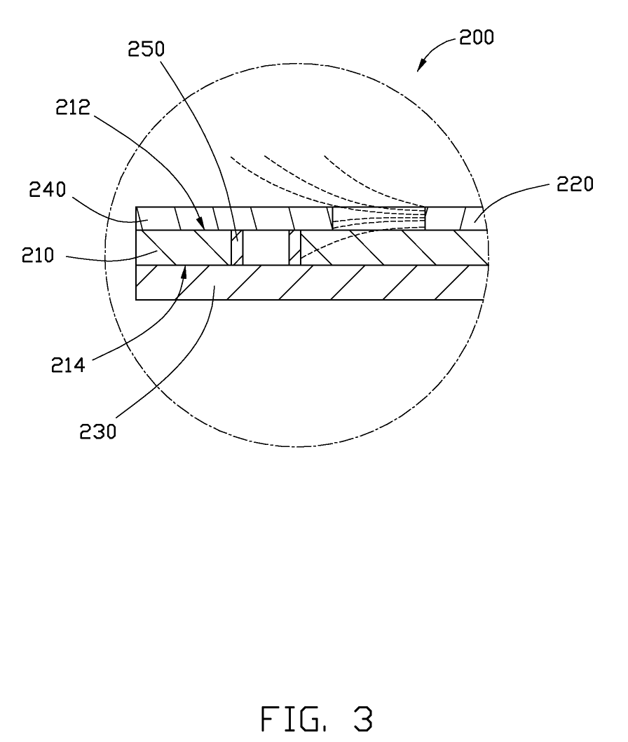

Referring to FIG. 3, in use, electromagnetic radiation (schematically shown by a bundle of parabola lines, i.e., electric field lines, travelling out of the edge of the power layer 220) is generated between the power layer 220 and the ground layer 230. In conventional PCBs, electromagnetic radiation escapes from the conventional PCBs at the edge of the PCBs. In this embodiment, as shown in FIG. 3, most of the electromagnetic field lines are captured by the EMI reducing layer 240 and the via holes 250.

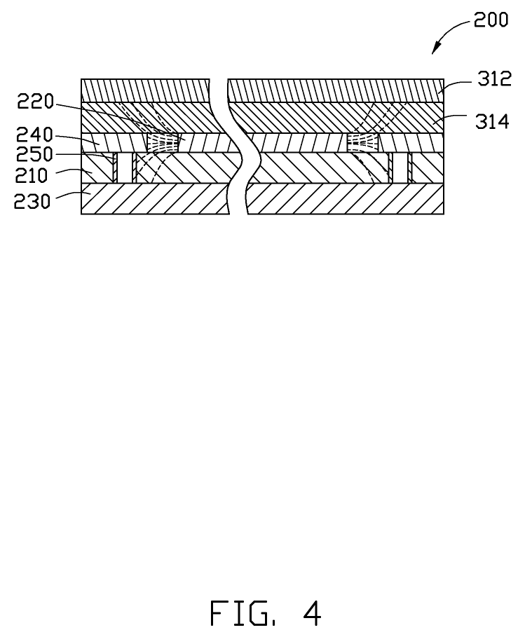

Further referring to FIG. 4, in practice, the PCB 200 typically further includes a signal dielectric layer 314 and a signal layer 312. The signal dielectric layer 314 is disposed on the power layer 220 and the EMI reducing layer 240. The signal layer 312 is disposed on the signal dielectric layer 314. The signal dielectric layer 314 is made of a dielectric material. The signal layer 312 is made of a conductive material and is patterned to form a signal circuit (not shown).

As shown in FIG. 4, in practical configuration, almost all of the electromagnetic radiation is captured by the via holes 250, the EMI reducing layer 240, and the signal layer 312. Thus, EMI is significantly reduced.

It should be mentioned that the number of the via holes 250 can be one in other alternative embodiments.

It should be noted that not only one dielectric layer 210 but more layers, including conductive and dielectric, can intervene between the power layer 220 and the ground layer 230. The via holes 250 are defined through these intervening layers.

While various exemplary and preferred embodiments have been described, it is to be understood that the invention is not limited thereto. To the contrary, various modifications and similar arrangements (as would be apparent to those skilled in the art) are intended to also be covered. Therefore, the scope of the appended claims should be the broadest interpretation so as to encompass all such modifications and similar arrangements.

What is claimed is:

1. A printed circuit board comprising:
a dielectric layer comprising a central portion and a periphery portion surrounding the central portion, the dielectric layer defining a via hole through the periphery portion;
a conductive ground layer adhered to a surface of the dielectric layer, covering both the central portion and the periphery portion;
a conductive power layer and a conductive function layer separately adhered to another surface of the dielectric layer facing away from the conductive ground layer, the conductive power layer covering the central portion, the conductive function layer substantially covering the periphery portion and being connected to the conductive ground layer via the at least one via hole.

2. The printed circuit board of claim 1, wherein the dielectric layer is made of a dielectric material selected from the group consisting of bakelite resin, fiberglass, epoxy resin, and glass-epoxy resin.

3. The printed circuit board of claim 1, wherein the conductive power layer is made of a conductive material selected from the group consisting of copper, aluminum, silver, platinum, and gold.

4. The printed circuit board of claim 1, wherein the conductive ground layer is made of a conductive material selected from the group consisting of copper, aluminum, silver, platinum, and gold.

5. The printed circuit board of claim 1, wherein the conductive function layer is made of a conductive material selected from the group consisting of copper, aluminum, silver, platinum, and gold.

6. The printed circuit board of claim 1, wherein the conductive power layer is about 20 H smaller than the conductive ground layer, where H is the height of the dielectric layer.

7. The printed circuit board of claim 1, further comprising a signal dielectric layer disposed on the conductive power layer and the conductive function layer and a signal layer disposed on the signal dielectric layer, the signal layer being configured for forming a signal circuit.
